(19) United States
(12) Patent Application Publication
(10) Pub. No.: US 2024/0363405 A1
(43) Pub. Date: Oct. 31, 2024

(54) Substrate Processing Method, Apparatus, and System

(71) Applicant: Tokyo Electron Limited, Tokyo (JP)

(72) Inventors: Masato SAKAMOTO, Hsin-chu City (TW); Tadahiro ISHIZAKA, Yamanashi (JP)

(21) Appl. No.: 18/634,671

(22) Filed: Apr. 12, 2024

(30) Foreign Application Priority Data
Apr. 25, 2023 (JP) 2023-071761

(51) Int. Cl. H01L 21/768; C23C 16/02; C23C 16/06; C23C 16/52; H01J 37/32

(52) U.S. Cl. CPC H01L 21/76862; C23C 16/0227; C23C 16/06; C23C 16/52; H01J 37/32137; H01J 37/32449; H01J 37/32568; H01L 21/7685; H01L 21/76867; H01L 21/76877; H01J 2237/335

(57) ABSTRACT

Provided is a substrate processing method for processing a substrate including a metal layer, the method comprising: supplying a halogen-containing gas to the substrate and reducing a metal oxide film formed on a surface of the metal layer; and supplying a reducing gas to the substrate and decreasing a residue remaining on the metal layer by supplying the halogen-containing gas.

### CROSS-REFERENCE TO RELATED APPLICATIONS

This application claims priority to Japanese Patent Application No. 2023-071761 filed on Apr. 25, 2023, the entire contents of which are incorporated herein by reference.

### TECHNICAL FIELD

The present disclosure relates to a substrate processing method, an apparatus, and a system.

### BACKGROUND

A semiconductor device manufacturing process includes a process of forming a metal wiring on a semiconductor wafer (hereinafter, referred to as “wafer”) that is a substrate. In the process of forming the wiring, it may be necessary to remove an oxide that may oxidize a surface of a metal layer. For example, Japanese Laid-open Patent Publication No. 2020-059916 discloses a method for removing a tungsten oxide film formed by natural oxidation of a surface layer of a tungsten layer.

### SUMMARY

The present disclosure provides a technique for decreasing a residue by supplying a halogen-containing gas for reducing a metal oxide film.

In accordance with an aspect of the present disclosure, there is provided a substrate processing method for processing a substrate including a metal layer, the method comprising: supplying a halogen-containing gas to the substrate and reducing a metal oxide film formed on a surface of the metal layer; and supplying a reducing gas to the substrate and decreasing a residue remaining on the metal layer by supplying the halogen-containing gas.

### BRIEF DESCRIPTION OF THE DRAWINGS

FIG. 1A is a vertical cross-sectional view of a recess formed in a wafer according to a first embodiment of the present disclosure.

FIG. 1B is a second vertical cross-sectional view of the recess.

FIG. 1C is a third vertical cross-sectional view of the recess.

FIG. 1D is a fourth vertical cross-sectional view of the recess.

FIG. 2 is a plan view of a substrate processing system according to a first embodiment.

FIG. 3 is a vertical cross-sectional view of a first processing module of the substrate processing system.

FIG. 4 is a flowchart showing a procedure of processing according to the first embodiment.

FIG. 5A is a first graph showing test results of a preliminary test.

FIG. 5B is a second graph showing test results of the preliminary test.

FIG. 5C is a third graph showing test results of the preliminary test.

FIG. 6A is a first graph showing test results of Example 1.

FIG. 6B is a second graph showing test results of Example 1.

FIG. 6C is a third graph showing test results of Example 1.

FIG. 7A is a first graph showing test results of Example 2.

FIG. 7B is a second graph showing test results of Example 2.

FIG. 7C is a third graph showing test results of Example 2.

### DETAILED DESCRIPTION

### First Embodiment

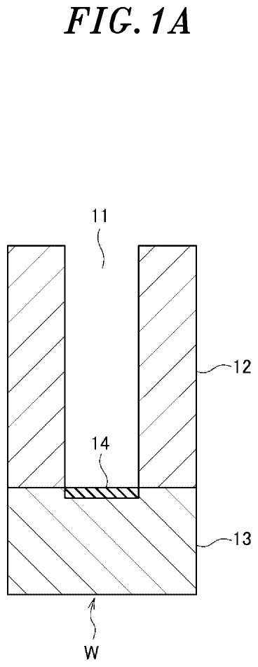

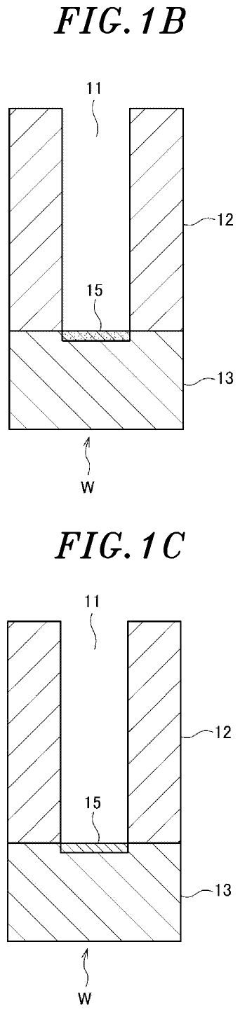

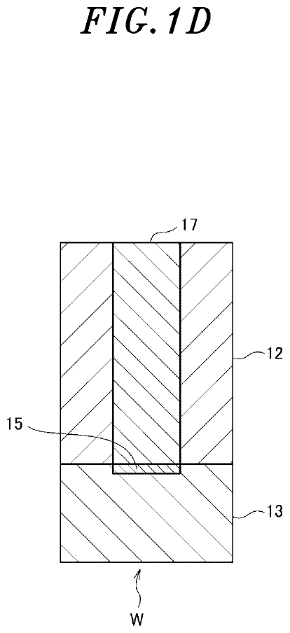

In order to describe a first embodiment of a substrate processing method of the present disclosure, a configuration of a wafer W that is a substrate to be processed will be described. FIG. 1A is a vertical cross sectional view showing a part of a surface layer of the wafer W before processing. A base layer of the wafer W is, e.g., a silicon layer made of silicon (Si). The illustration of the silicon layer is omitted.

A silicon oxide (SiOₓ) layer 12 is formed above the silicon layer. The silicon oxide layer has a plurality of vertically elongated recesses 11 that are formed by performing etching from the top to be opened upward. Although a silicon nitride (SiN) layer used in the etching is formed on the sidewall of the recess 11, the illustration thereof is omitted in FIGS. 1A to 1D. A tungsten (W) layer 13 that is a first metal layer is exposed at the bottom portion of the recess 11. The tungsten layer 13 constitutes a metal wiring of a semiconductor device manufactured from the wafer W, and a lower end thereof is laminated on the above-described silicon layer via a titanium nitride (TiN) layer (not shown), for example. A tungsten oxide film 14, which is a metal oxide film that is naturally oxidized when the wafer W is transferred in the atmosphere, for example, is formed on the surface of the tungsten layer 13 facing into the recess 11.

In the wafer W, a ruthenium (Ru) layer 17 is formed as a second metal layer in the recess 11, thereby forming a metal wiring. On the other hand, if the tungsten oxide film 14 is formed between the tungsten layer 13 and the ruthenium layer 17, the resistance value of the metal wiring increases and, also, the embedding failure of the ruthenium layer 17 occurs. Therefore, in the substrate processing method of the present disclosure, a step of reducing the tungsten oxide film 14 using a halogen-containing gas, e.g., titanium tetrachloride (TiCl₄) gas, is performed. TiCl₄ gas effectively reduces the tungsten oxide film 14, but titanium (Ti) or chlorine (CI) contained in TiCl₄ gas remains in the tungsten film after reduction (“reduced tungsten film 15” to be described later). Titanium is also a factor that increases the resistance value of the metal wiring, so that the metal wiring may be etched when HCl is generated from chlorine. Further, chlorine may inhibit the formation of the ruthenium layer 17.

Therefore, in the present embodiment, a step of decreasing the residue in the reduced tungsten film 15 is performed, and then, a step of forming the ruthenium layer 17 is performed. Hereinafter, the step of reducing the tungsten oxide film 14 may be referred to as “reduction step,” the step of decreasing the residue may be referred to as “removal step,” and the step of forming the ruthenium layer 17 may be referred to as “film formation step.”

Hereinafter, a series of processes will be described with reference to FIGS. 1B to 4 showing changes in the surface of the wafer W. During the series of processes, the environment around the wafer W is maintained in a vacuum atmosphere. In other words, the wafer W is not exposed to the atmosphere during the series of processes. Therefore, each step is performed in a state where the wafer W is stored in the processing chamber.

First, the reduction step for supplying TiCl₄ gas that is a halogen-containing gas to the wafer W is performed. In this case, TiCl₄ gas is supplied to the wafer W without activation such as turning into plasma. Accordingly, a reducing atmosphere is generated in the processing chamber in which the wafer W is accommodated. As a result, the tungsten oxide film 14 reacts with TiCl₄ gas, and becomes the reduced tungsten film 15 shown in FIG. 1B. The reduced tungsten film 15 is obtained by reducing the tungsten oxide film 14, and has a lower oxygen content than that of the tungsten oxide film 14.

In this case, the reduced tungsten film 15 contains chlorine or titanium, which is the residues of titanium tetrachloride that has reacted with the tungsten oxide film 14. “Containing the residue of titanium tetrachloride” does not necessarily indicate that the residue is contained in the reduced tungsten film 15, and may also include a case where the residue is adhered to the surface. Hereinafter, the residue of titanium tetrachloride may be simply referred to as “residue.” In FIG. 1B, the reduced tungsten film 15 containing a large amount of residue after the reduction step is indicated by a dot-shaped diagonal hatching inclined downward to the right.

Next, the removal step for removing the residue remaining on the reduced tungsten film 15 of the wafer W is performed. In the present embodiment, the residue is removed by supplying a reducing gas to the wafer W including the reduced tungsten film 15. The reducing gas is used for generating a reducing atmosphere in a space where the wafer W is placed during processing, and may be, e.g., hydrogen gas that has been turned into plasma (hydrogen gas plasma). Further, if accelerated high-energy hydrogen ions collide with the surface of the wafer W during the supply of the hydrogen gas plasma, the SiOₓ layer 12 forming the recess 11 may be damaged. Specifically, the recess 11 may be partially expanded by partial etching of the SiOₓ layer 12 forming the opening portion or the intermediate region of the recess 11 due to ion collision.

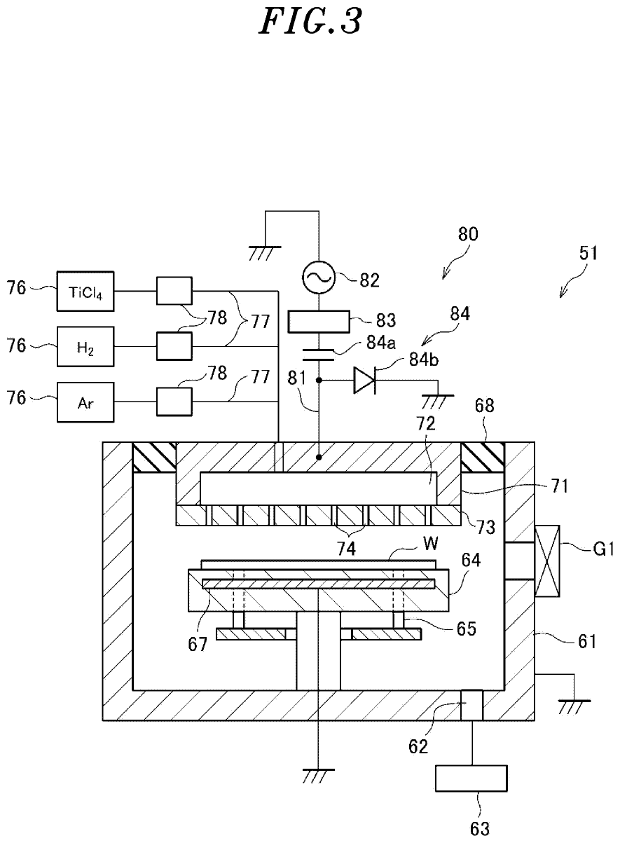

Therefore, it is preferable that low-energy hydrogen gas plasma containing energy-suppressed ions and hydrogen radicals is supplied as the hydrogen gas plasma supplied to the wafer W during the removal step. A specific configuration of a substrate processing module (first processing module 51) for supplying low-energy hydrogen gas plasma will be described later with reference to FIG. 3. When the hydrogen gas that has been turned into plasma is supplied to the wafer W, enters the recess 11, and reaches the reduced tungsten film 15, the residue reacts with active species in the hydrogen gas plasma, thereby removing the residue (see FIG. 1C). In FIG. 1C, the reduced tungsten film 15 that has been subjected to the removal step and has a reduced content of residue is indicated by dot-shaped diagonal hatching inclined downward to the right.

Further, by using hydrogen gas plasma that is a reducing gas in the residue removal step, the content of oxygen remaining after the reduction step is decreased. As a result, it is possible to further suppress the occurrence of embedding failure of the ruthenium layer 17 in the reduced tungsten film 15 and reduce a wiring resistance.

Next, a film formation step for forming the ruthenium layer 17 on the wafer W by CVD is performed. The film forming gas is, e.g., Ru₃(CO)₁₂ (triruthenium dodecacarbonyl) gas. Hereinafter, Ru₃(CO)₁₂ gas may also be referred to as “DCR gas.” Accordingly, the ruthenium (Ru) layer 17 is formed to be embedded in the recess 11 above the reduced tungsten film 15. Then, the Ru layer 17 formed on the upper surface of the SiOₓ layer 12 is removed by chemical mechanical polishing (CMP), so that ruthenium is embedded in the recess 11 as shown in FIG. 1D. The ruthenium layer 17 and the tungsten layer 13 (the reduced tungsten film 15) thus formed constitute a wiring having a low resistance and a low content of oxygen or residue on the wafer W.

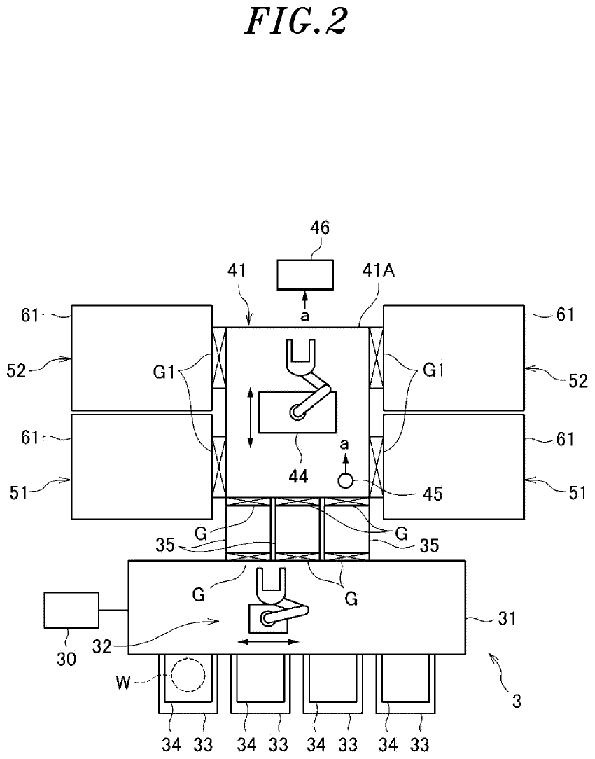

A substrate processing system 1 that is an embodiment of a substrate processing system capable of performing the above-described series of processes will be described with reference to the plan view of FIG. 2. The substrate processing system 1 includes a loader module 31, load-lock modules 35, a vacuum transfer module 41 corresponding to a vacuum transfer device, first processing modules 51 for performing a reduction step and a removal step, and second processing modules 52 for performing a film formation step. The first processing module corresponds to “apparatus for processing a substrate” and “first apparatus” to be described in the claims, and the second processing module 52 corresponds to “second apparatus” to be described in the claims.

The loader module 31, the load-lock modules 35, and the vacuum transfer module 41 are arranged linearly in that order in the front-rear direction. In the following description of the substrate processing system 1, the side where the loader module 31 is located will be referred to as “front side” and the side where the vacuum transfer module 41 is located will be referred to as “rear side.”

The loader module 31 includes a housing whose inner pressure is maintained at an atmospheric pressure, a transfer mechanism 32 for a wafer W that is disposed in the housing, and load ports 33. In this example, four load ports 33 are arranged side by side on the front side of the housing. A transfer container 34 for storing wafers W, which is referred to as “front opening unified pod (FOUP),” is disposed in each load port 33. The transfer mechanism 32 is configured as, e.g., a multi-joint arm capable of moving to the left and right, and can transfer the wafer W between the transfer container 34 on each load port 33 and each load-lock module 35.

In this example, three load-lock modules 35 are arranged side by side when viewed from the front side. Each load-lock module 35 has a housing, and the housing is connected to the loader module 31 and the vacuum transfer module 41 via gate valves G disposed on the front and rear sides, respectively. When the gate valves G on the front and rear sides of the housing are closed, the pressure in the housing can be changed between an atmospheric pressure and a vacuum pressure. Further, a stage (not shown) on which the wafer W is placed is disposed in the housing, and the stage is configured to transfer the wafer W to and from the transfer mechanism 32 and a vacuum transfer mechanism 44 (to be described later) that access the corresponding load-lock module 35.

The vacuum transfer module 41 includes a housing 41A and a vacuum transfer mechanism 44 disposed in the housing 41A. An exhaust port 45 is opened at the housing 41A, and one end of an exhaust line is connected to the exhaust port 45. The other end of the exhaust line is connected to an exhaust mechanism 46 including, e.g., a turbo molecular pump, and the inside of the housing 41A is maintained in a vacuum atmosphere by evacuation from the exhaust port 45 by the exhaust mechanism 46. The inside of the housing 41A that is maintained in the vacuum atmosphere by the exhaust mechanism 46 corresponds to a transfer path maintained in a vacuum atmosphere where the wafer W is transferred.

The first processing modules 51 and the second processing modules 52 arranged in the front-rear direction are connected to the left and right sides of the housing 41A of the vacuum transfer module 41 via gate valves G1 when viewed from the front side. The wafer W is transferred between the first processing modules 51, the second processing modules 52, and the load-lock modules 35 by the vacuum transfer mechanism 44 configured as a multi-joint arm capable of moving in the front-rear direction.

The processes performed in the processing modules 51 and 52 correspond to the above-described series of processes. The reduction step and the removal step are performed in the first processing modules 51, and the film formation step is performed in the second processing modules 52. Each of the processing modules 51 and 52 includes a processing chamber 61 evacuated to a vacuum atmosphere, and each step is performed in the processing chamber 61. Therefore, the reduction step and the removal step are performed on the wafer W in the same processing chamber 61.

The substrate processing system 1 includes a controller 30 that is a computer, and the controller 30 includes a program. The program has instructions (steps) for processing the wafer W and transferring the wafer W as described above. The program is stored in a storage medium such as a compact disk, a hard disk, a DVD, or the like, and installed in the controller 30. The controller 30 outputs control signals to individual components of the substrate processing system 1 based on the program, and controls the operations of the individual components. Specifically, the operations of the processing modules 51 and 52, the opening/closing of the gate valves G and G1, the operation of the transfer mechanism 32, the operation of the vacuum transfer mechanism 44, the operation of the exhaust mechanism 46, the switching of the pressure in the load-lock modules 35, and the like are controlled. Specifically, the control of the operations of the processing modules 51 and 52 includes, e.g., the control of the temperature of the wafer W by power supply to a heater 66 to be described later, the control of supply and supply stop of each gas into the processing chamber 61, and the control of plasma generation by turning on/off a radio frequency (RF) power supply 82 to be described later.

First, the wafer W in the substrate processing system 1 is transferred in the order of the transfer container 34→the loader module 31→the load-lock module→the vacuum transfer module 41. Then, the wafer W is transferred in the order of the first processing module 51→the vacuum transfer module 41→the second processing module 52. Thereafter, the wafer W is transferred in the order of the vacuum transfer module 41→the load-lock module 35→the loader module 31, and is returned to the transfer container 34.

Next, between the processing modules 51 and 52, the first processing module 51 for performing the reduction step and the removal step will be described with reference to the vertical cross-sectional view of FIG. 3. As described above, the transfer port for the wafer W is formed on the sidewall of the processing chamber 61 of the first processing module 51, and is provided with the gate valve G1 for opening/closing the transfer port. Further, the processing chamber 61 is grounded. One end of the exhaust line 62 is connected to be opened on the wall surface of the processing chamber 61, and the processing chamber 61 is exhausted to a vacuum atmosphere of a desired pressure by the exhaust mechanism 63 disposed at the other end of the exhaust line 62. Specifically, a pressure in the processing chamber 61 is set to about 1330 Pa (10 Torr) in the reduction step, and is set to about 133 Pa (1 Torr) in the removal step. Further, the exhaust mechanism 63 performs an exhaust operation for about 10 seconds between the reduction step and the removal step to replace the gas in the processing chamber 61.

A substrate placing table 64 on which the wafer W is placed is disposed in the processing chamber 61, and the wafer W is transferred between the substrate placing table 64 and the vacuum transfer mechanism 44 by lift pins 65 configured to protrude from and retract below the upper surface of the substrate placing table 64. A heater (not shown) is embedded in the substrate placing table 64 to heat the wafer W to a preset temperature during processing. Specifically, the temperature of the heater is controlled such that the wafer W is heated to about 400° C. in the reduction step and the removal step. Further, a grounded electrode 67 for plasma generation is embedded in the substrate placing table 64, thereby constituting a lower electrode.

An opening is formed at the upper part of the processing chamber 61, and a shower head 71 is fitted into the opening via an insulating member 68 to face the substrate placing table 64. The shower head 71 is made of a metal and has a cylindrical shape as a whole. The shower head 71 has an inner space 72 serving as a gas diffusion space, and a shower plate 73 forming a bottom surface. The shower plate 73 has a plurality of gas injection holes 74 communicating with the inner space 72. Gas inlet holes for supplying various gases to the inner space 72 are formed in the shower head 71. The gas inlet holes are connected to a downstream end of a gas supply part 75 for supplying various gases, and is configured to supply various gases to the inner space 72.

The gas supply part 75 includes gas supply sources 76 for supplying a halogen-containing gas, a reducing gas, and an argon (Ar) gas as a plasma generation gas, gas supply lines 77 disposed to correspond to the gas supply sources 76, and flow rate controllers 78 disposed to correspond to the gas supply lines 77. The flow rate controllers 78 are configured as flow rate control mechanisms such as valves and mass flow controllers, and can supply gases into the processing chamber 61 at individually adjusted flow rates by controlling supply and supply stop of the gases to the downstream side in response to the control signal from the controller 30. Ar gas is not necessarily supplied as an auxiliary gas for plasma generation, and may be supplied as an inert gas together with a halogen-containing gas in the reduction step. The flow rate ratio of the halogen-containing gas to the Ar gas in the reduction step is set to, e.g., about 1:10, and the flow ratio of the reducing gas to the Ar gas in the removal step is set to, e.g., about 1:120.

The shower head 71, which is an upper electrode, is configured to be connected to the RF power supply 82 through a power supply line 81. The RF power supply 82 generates capacitively coupled plasma of a reducing gas between the shower head 71 and the substrate placing table 64 by supplying an RF power of 300 W having a frequency of 10 kHz to 60 MHz to the shower head 71, for example. A matching device 83 is connected to the downstream side of the RF power supply 82 of the power supply line 81. The matching device 83 matches a load impedance with an internal (or output) impedance of the RF power supply 82.

A voltage waveform shaping part 84 for shaping a voltage waveform of an RF power is disposed between the RF power supply 82 and the upper electrode, more specifically, on the downstream side of the matching box 83 of the power supply line 81 to suppress a positive voltage (plus voltage) of the RF voltages applied to the upper electrode. In the present embodiment, a voltage waveform shaping part disclosed in Japanese Patent Application Publication No. 2022-018062 is used as the voltage waveform shaping part 84. In other words, the voltage waveform shaping part 84 includes a capacitor 84a disposed on the downstream side of the matching device 83, and a grounding circuit branched from the downstream side of the capacitor 84a and grounded via a diode 84b. A capacitor having a capacitance that is sufficient to reduce an impedance when viewed from the RF power supply 82 is used as the capacitor 84a.

If the first processing module 51 is not provided with the voltage waveform shaping part 84, a sheath voltage (difference between a plasma potential and a substrate potential) increases as a positive voltage when the RF power from the RF power supply 82 outputs a positive voltage. Due to the sheath voltage, positively charged hydrogen ions contained in the plasma are accelerated toward the wafer W, where the potential becomes zero, and collide with the wafer W with high kinetic energy.

On the other hand, in the voltage waveform shaping part 84, when the RF power supply 82 outputs a positive voltage, the diode 84b causes a current to flow to the ground side to suppress the application of the positive voltage to the upper electrode and reduce the sheath voltage, thereby suppressing an increase in the ion energy. In this case, in the capacitor 84a, the power is accumulated and the accumulated power is inputted to a plasma region on the upper electrode side together with the RF power outputted when the RF power supply 82 outputs a negative voltage, thereby effectively increasing a plasma density. The above-described plasma supply mechanism 80 including the voltage waveform shaping part 84, the RF power supply 82, and the like can generate high-density plasma containing low-energy ions capable of preventing damage to the wafer W caused by ions.

Next, the difference between the first processing module 51 and the second processing module 52 will be mainly described. Since the plasma processing is not performed in the second processing module 52, the plasma supply mechanism 80 and the electrode 67 of the substrate placing table 64 may not be provided, and plasma may not be generated in the processing chamber 61. Further, gases used in the above-described film formation step are stored in the gas supply sources 76 for supplying gases into the processing chamber 61. The second processing module 52 has substantially the same configuration as that of the first processing module 51 except the above-described differences. However, the temperature of the wafer W is set to, e.g., 200° C. or less, which is lower than that during the reduction step and the removal step in the first processing module 51.

The operation of performing a series of processes on the wafer W using the substrate processing system 1 configured as described above will be described with reference to FIGS. 2 to 4. First, when the vacuum transfer mechanism 44 in the vacuum transfer module 41 receives the wafer W to be processed from the load-lock module 35, the gate valve G1 of the first processing module 51 is opened, and the vacuum transfer mechanism 44 transfers the wafer W into the processing chamber 61 from the loading port. Then, the wafer W is transferred from the vacuum transfer mechanism 44 to the substrate placing table 64 using the lift pins 65, and the vacuum transfer mechanism 44 is retracted from the processing chamber 61. Then, the gate valve G1 is closed.

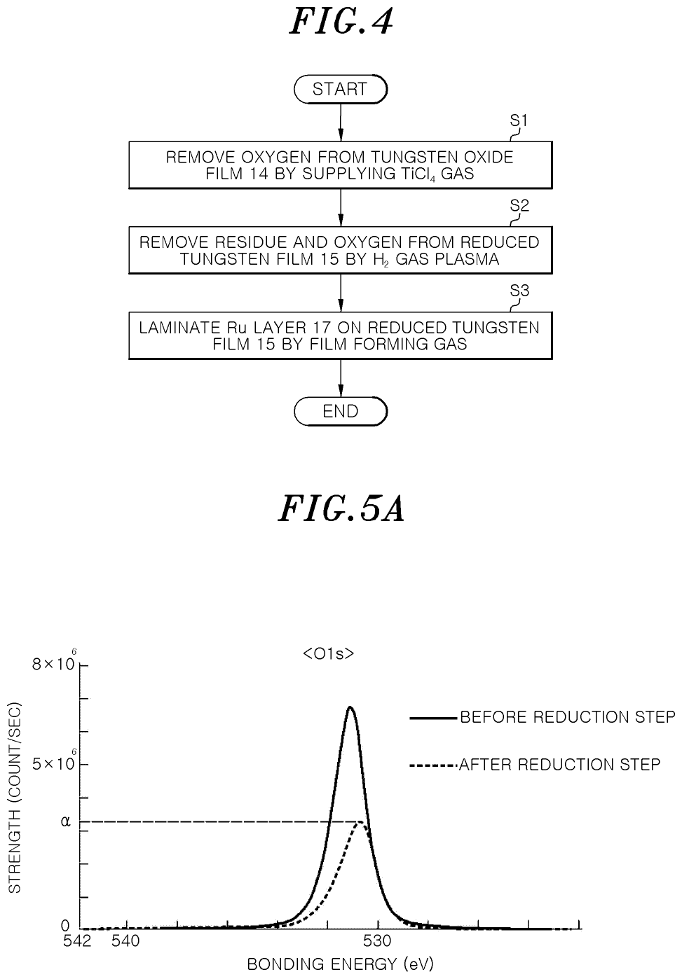

First, the reduction step is performed. The pressure in the processing chamber 61 and the temperature of the wafer Ware adjusted based on the setting of the recipe in the reduction step. Next, TiCl₄ gas is supplied into the processing chamber 61 together with Ar gas. In this case, the RF power supply from the RF power supply 82 to the shower head 71 is not performed. Due to the reaction with the TiCl₄ gas, the tungsten oxide film 14 on the wafer W is reduced (step S1 in FIG. 4) and becomes the reduced tungsten film 15 containing a residue (see FIG. 1B).

Next, the removal step is performed. The pressure and the temperature in the processing chamber 61 are adjusted based on the setting of the recipe in the removing step. Since the set temperature of the wafer W in the removal step is substantially the same range as that of the wafer W in the reduction step, the throughput can be improved by performing both the reduction step and the removal step in the same processing chamber 61, i.e., in the same first processing module 51. In the removal step, hydrogen gas and Ar gas are supplied and, also, the RF power is applied from the RF power supply 82 to the shower head 71. In this case, by supplying the RF power whose voltage waveform has been shaped by the above-described voltage waveform shaping part 84, low-energy and high-density hydrogen gas plasma containing energy-suppressed hydrogen ions and hydrogen radicals can be generated. As described above, damage to the SiOₓ layer 12 can be suppressed by supplying low-energy hydrogen gas plasma.

Due to the reaction with the hydrogen gas in a plasma state, the residue is removed from the reduced tungsten film 15 exposed into the recess 11, and the reduction can proceed further (step S2 in FIG. 4, see FIG. 1C). In this case, the residue adhered inside the recess 11 is also removed by the hydrogen gas in a plasma state, so that deterioration of the embedding property of the ruthenium layer 17 can also be suppressed.

In accordance with the reduction step and the removal step described above, it is possible to suppress damage to the recess 11 and easily maintain the original shape of the recess 11 by utilizing the reduction in which the tungsten oxide film 14 is not physically removed unlike etching and the low-energy hydrogen gas plasma. By forming the ruthenium layer 17 in the recess 11 whose original shape is maintained, the formation accuracy of a metal wiring is improved. Further, by preparing a gas type capable of performing the reduction step and the removal step in the gas supply source 76 connected to the first processing module 51 provided with the plasma supply mechanism 80 including the voltage waveform shaping part 84, such steps can be efficiently performed in the same module.

When the removal step is completed, the wafer W is unloaded from the first processing module 51 in the reverse order of the loading process. Next, the wafer W is loaded into the second processing module 52 in the same order of the process of loading the wafer W into the first processing module 51, and then is subjected to the film formation step. When the wafer W is transferred from the first processing module 51 to the second processing module 52, the wafer W is not exposed to the atmospheric atmosphere because the wafer W is transferred via the vacuum transfer module 41 serving as the transfer path maintained in a vacuum atmosphere. Therefore, the reduced tungsten film 15 that has been reduced by the reduction step and the removal step can be prevented from being oxidized again by the atmospheric atmosphere.

Next, the film formation step is performed. In the second processing module 52 whose temperature and pressure have been adjusted based on the setting of the recipe in the film formation step, a DCR gas that has not turned into plasma is supplied into the processing chamber 61. The ruthenium layer 17 is laminated on the reduced tungsten film 15 of the wafer W by the DCR gas (step S3), and a wiring layer in which the tungsten layer 13 and the ruthenium layer 17 are laminated is formed in the recess 11. Since a good embedding property of the ruthenium layer 17 into the recess 11 from which the residue has been removed in the removal step can be obtained and the reduced tungsten film 15 is formed at the upper part of the tungsten film 13, it is possible to form a wiring layer having a low resistance value.

### Modification of First Embodiment

In the first embodiment, low-energy plasma processing is performed by the voltage waveform shaping part 84, so that the removal step in which a reducing power is high and damage to the recess 11 is suppressed is realized. On the other hand, if the film formation step allows deformation of the recess 11, the removal step may be performed in a first processing module 51A (not shown) that does not include the voltage waveform shaping part 84. In other words, in the removal step, plasma of a reducing gas whose energy is not reduced may be used. In this case, the effect similar to that of Example 1-2 to be described later is expected.

### Second Embodiment

In the substrate processing system 1 according to the second embodiment, the same substrate processing system 1 as that used in the first embodiment is used, but the removal step is performed using plasma containing ammonia (NH₃) gas as a reducing gas. Specifically, the gas supply part 75 of the first processing module 51 is configured to supply nitrogen (N₂) gas as an auxiliary gas to the mixed gas of ammonia gas and hydrogen gas and at approximately the same flow rate. Specifically, the flow rate ratio of hydrogen gas to ammonia gas is from 0.4 to 1.5, and preferably from 1 to 1.2.

The low-energy plasma of the mixed gas of ammonia gas and hydrogen gas is generated using the gas supply part 75 and the plasma supply mechanism 80 configured as described above. Accordingly, the step of removing the residue from the reduced tungsten film 15 is performed while suppressing damage to the recess 11. In the case of using the reducing gas of the present embodiment, chlorine can be effectively reduced by ammonia gas, and nitriding after the removal step can be suppressed by hydrogen gas. The pressure in the processing chamber 61 in the removal step is approximately ⅓ of that in the reduction step.

### Modification of second embodiment

When the reducing gas used in the removal step contains ammonia gas, it is unnecessary to convert the gas into plasma. In other words, in the removal step, the mixed gas of ammonia gas and hydrogen may be supplied into the processing chamber 61 without being turned into plasma. In this Modification, plasma is not generated, so that the first processing module 51 may not include the plasma supply mechanism 80. When plasma is not used, the reducing gas supply time is approximately three times longer than that in the second embodiment using plasma.

### Modifications

In the first and second embodiments and Modifications thereof, the reduction step and the removal step are performed in the same first processing module 51 in terms of efficiency. However, they may be performed in separate processing modules.

Further, the halogen-containing gas may be, e.g., another halogen-containing gas without being limited to TiCl₄ gas. Specifically, boron trichloride (BCl₃) gas, tungsten hexafluoride (WF₆) gas, tungsten pentachloride (WC₁₅) gas, tungsten hexachloride (WC₁₆) gas, or the like may be used. In addition, a halogen-containing gas composed of molybdenum (Mo), or a halogen-containing gas composed of Ti other than TiCl₄ gas may be used. Although the case in which Ar gas as an inert gas is supplied together with the halogen-containing gas has been described, the inert gas is not limited to Ar gas and may be, e.g., nitrogen gas. The above-described flow rate ratios of gases are merely examples, and may be changed appropriately.

Ru₃(CO)₁₂ gas is not necessarily used for the formation of the ruthenium layer 17 in the recess 11. For example, a gas containing (2,4-dimethylpentadienyl)(ethylcyclopentadienyl) ruthenium[(Ru(DMPD)(EtCp)], bis(2, 4-dimethylpentadienyl) Ruthenium[Ru(DMPD) 2], (4-dimethylpentadienyl)(methylcyclopentadienyl) Ruthenium[(Ru(DMPD)(MeCp)], Bis(Cyclopentadienyl) Ruthenium[(Ru(C5H5) 2], Cis-dicarbonyl bis(5-methylhexane-2, 4-dionate) ruthenium(II), bis(ethylcyclopentadienyl) Ruthenium(II)[Ru(EtCp) 2], Ru(chd)(ipmb), Ru(EtBz)(EtCHD), or the like may be used instead of Ru₃(CO)₁₂ to perform the formation of the ruthenium layer 17.

Although it is preferable to form the ruthenium layer 17 as a second metal film formed in the recess 11 in order to reduce a wiring resistance value, the present disclosure is not limited to the formation of the ruthenium layer 17. For example, by supplying a film forming gas, even if a molybdenum layer or a tungsten layer is formed instead of the ruthenium layer 17, a relatively small wiring resistance value can be obtained, which is preferable. For the same reason, a first metal film forming the bottom surface of the recess 11 is not limited to the tungsten layer 13, but may be a ruthenium layer, a molybdenum layer, a cobalt layer, or a titanium layer. The titanium layer may be the above-described titanium nitride layer formed under the tungsten layer 13.

Further, it should be noted that the embodiments of the present disclosure are illustrative in all respects and are not restrictive. The above-described embodiments can be embodied in various forms. Further, the above-described embodiments may be omitted, replaced, changed, or combined in various forms without departing from the scope of the appended claims and the gist thereof.

### EXAMPLES

### (Preliminary Test)

In the tungsten oxide film 14 before the series of processes and the reduced tungsten film 15 that has been subjected to only the reduction step of the present disclosure, the changes in the amount of oxygen and residue due to the reduction step were monitored using X-ray photoelectron spectroscopy (XPS). Titanium and chlorine (CI) generated from TiCl₄ gas were measured as the residue.

### A. Preliminary Test Conditions

The reducing step of the first embodiment is performed on the tungsten oxide film 14 formed by natural oxidation of the surface, using the substrate processing system 1 of the first embodiment and a bare wafer in which a TiN layer and the tungsten layer 13 are laminated on the surface of a silicon wafer. XPS analysis was performed on the tungsten oxide film 14 before the reduction step and the reduced tungsten film 15 after the reduction step.

### B. Preliminary Test Results

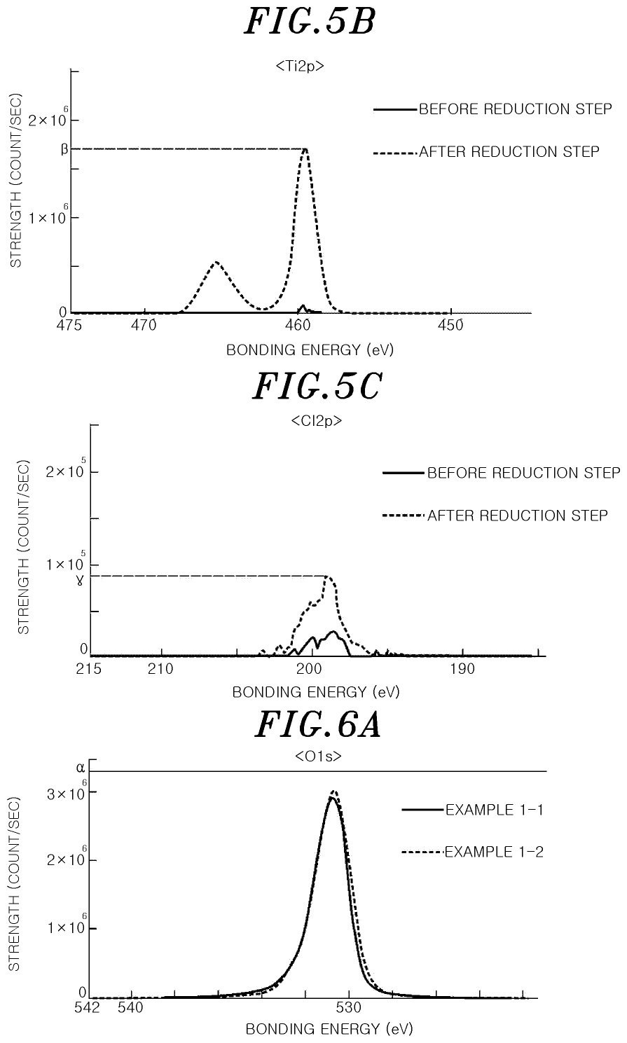

In the XPS analysis of the tungsten oxide film 14 before the reduction step and the reduced tungsten film 15 after the reduction step, the spectrum of electrons emitted from the 1s orbit of O atoms and the spectrum of electrons emitted from the 2p orbit of Ti atoms, and the spectrum of electrons emitted from the 2p orbit of Cl atoms are shown in FIGS. 5A, 5B, and 5C. As shown in FIG. 5A, the peak representing oxygen is lower after the reduction step than before the reduction step, which indicates that the tungsten oxide film 14 was effectively reduced and removed by the reduction step. Further, as shown in FIGS. 5B and 5C, the peaks representing titanium and chlorine is higher after the reduction step than before the reduction step, which indicates that a large amount of the residue remains in the reduced tungsten film 15 due to the reduction step. For comparison with the following Test Examples, the peak values of the photoelectron spectra of O atoms, Ti atoms, and Cl atoms after the reduction step are indicated as a, p, and y, respectively.

### Tests

The reduction step similar to that in the preliminary test and the removal step in the first and second embodiments (including Modifications thereof) were performed, and the amount of oxygen and residue in the reduced tungsten film 15 after the reduction step and the removal step were analyzed by XPS analysis. The oxygen and the residue that are the same as those in the preliminary test were analyzed.

### A. Test Conditions

### Example 1

The reduction step and the removal step for the first embodiment and Modification of the first embodiment were performed using the substrate processing system 1 that is the same as that used in the preliminary test and two wafers W. Specifically, in Example 1-1, the reduction step and the removal step using hydrogen gas plasma according to the first embodiment were performed on the wafer W, and the reduced tungsten film 15 after the removal step was subjected to the XPS analysis. In Example 1-2, the reduction step and the removal step for Modification (the RF power without voltage shaping using the voltage waveform shaping part 84 was applied to form the hydrogen gas plasma) of the first embodiment were performed on the wafer W, and the reduced tungsten film 15 after the removal step was subjected to the XPS analysis. In Examples 1-1 and 1-2, each of the TiCl₄ gas and the reducing gas were supplied once. The supply time of each reducing gas was set to, e.g., 20 seconds, and the supply time of each TiCl₄ gas was set to be at least 10 times longer than the supply time of each reducing gas. In order to check the difference in the reduced tungsten film 15 depending on the difference in the methods of Examples, in Test examples 1-1 and 1-2, and the following Examples, the operating conditions of each mechanism, such as the temperature of the substrate placing table 64 and the like, were set to be the same in the same step unless otherwise specified.

### Example 2

The reduction step and the removal step for the second embodiment and Modification of the second embodiment were performed using the substrate processing system 1 that is the same as that used in Example 1 and two wafers W. Specifically, in Example 2-1, the reduction step and the removal step in the second embodiment (supplying a mixed gas of ammonia gas and hydrogen gas, and plasma of nitrogen gas) were performed on the wafer W, and the reduced tungsten film 15 after the removal step was subjected to the XPS analysis. In Example 2-2, the reduction step and the removal step in Modification (supplying ammonia gas that was not turned into plasma) of the second embodiment were performed on the wafer W, and the reduced tungsten film 15 after the removal step was subjected to the XPS analysis. In Test examples 2-1 and 2-2, the pressure in the processing chamber 61 during each removal step was set to be lower than the pressure in the processing chamber 61 during the reduction step, and was set to be higher than the pressure in the processing chamber 61 during the removal step of Example 1. The reducing gas supply time in Example 2-2 was set to be three times longer than that in Example 2-1.

### Example 3

In Example 3, it was checked whether or not the amount of oxygen or residue has changed at the time of changing the setting conditions of the removal step based on Example 1-1. In Example 3-1, the supply time of the halogen-containing gas was the same as that in Example 1-1, and the frequency of the supply of the halogen-containing gas and the reducing gas was set to 4 times, 8 times, and 12 times. Then, the XPS analysis was performed to check whether or not the amount of oxygen or residue has changed depending on the frequency of the supply. In Example 3-2, the removal step was performed while changing the RF power to 300 W, 600 W, and 900 W, and the XPS analysis was performed to check whether or not the amount of oxygen or residue has changed depending on the magnitude of the RF power.

B. Test results

### Example 1

The XPS analysis results for Example 1 are shown in FIGS. 6A to 6C. In FIGS. 6A to 6C, the spectrum of the reduced tungsten film 15 of Example 1-1 is indicated by a solid line, and the spectrum of the reduced tungsten film 15 of Example 1-2 is indicated by a dashed line. Further, the positions a, p, and y of the peaks of O atoms, Ti atoms, and Cl atoms after the reduction step in the preliminary test are also shown. In Example 1-1 using low-energy hydrogen plasma, the reduced tungsten film 15 after the reduction step was further reduced, so that the oxygen content was decreased, and the residue from titanium was also decreased. However, the residue from chlorine was hardly decreased. On the other hand, even in Example 1-2 in which hydrogen plasma was generated by supplying the RF power without voltage shaping, the reduced tungsten film 15 after the reduction step was further reduced, so that the oxygen content was decreased and, also, the residue from titanium and the residue from chlorine were decreased. In both Examples 1-1 and 1-2, the residue caused by performing the reduction step was removed, and the reduction proceeded further.

### Example 2

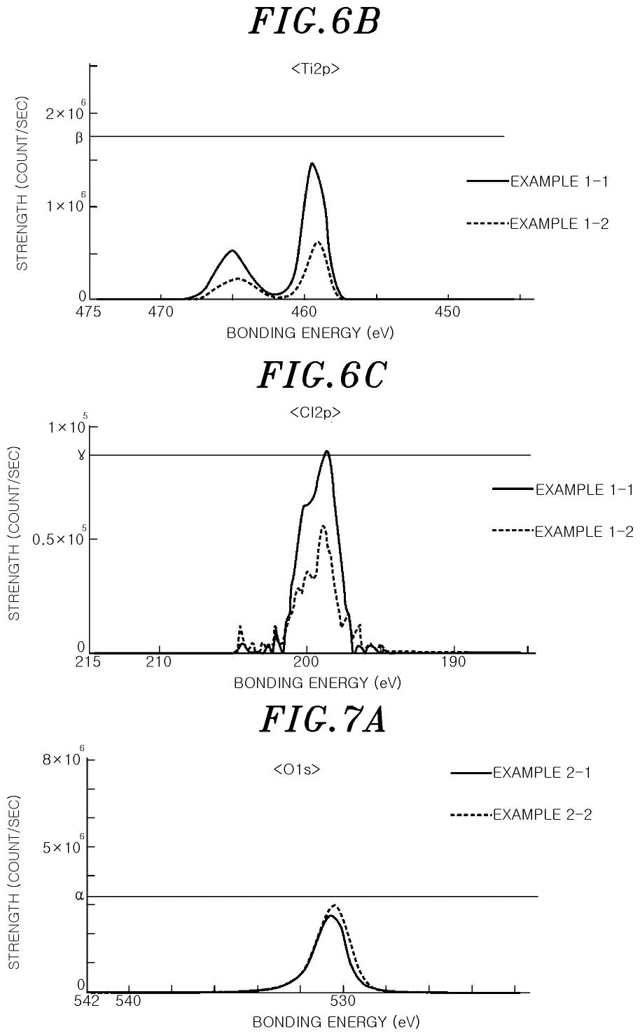

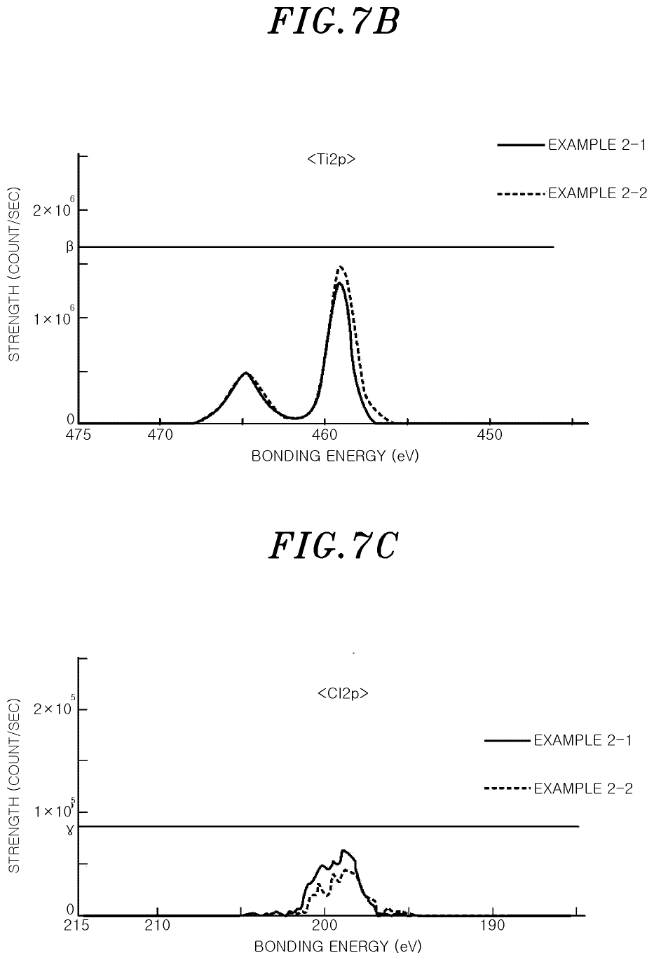

The XPS analysis results for Example 2 are shown in FIGS. 7A to 7C. In FIGS. 7A to 7C, the spectrum of the reduced tungsten film 15 of Example 2-1 is indicated by a solid line, and the spectrum of the reduced tungsten film 15 of Example 2-2 is indicated by a dashed line. In Example 2-1 using ammonia-containing gas plasma containing low-energy ions and Example 2-2 using ammonia gas that has not turned into plasma, the reduced tungsten film 15 after the reduction step was further reduced, so that the residue from titanium and the residue from chlorine were decreased.

From the above results, it was found that by performing the reduction step using a halogen-containing gas and the removal step in which the plasma supply mechanism 80 supplies reducing gas plasma containing low-energy ions, the tungsten oxide film 14 can be reduced and the amount of residue caused by the reduction process can be decreased. Further, it was also found that in the case of using ammonia gas as a reducing gas, the same effect can be obtained even if a gas that has not turned into plasma is used.

### Example 3

The analysis data of Examples 3-1 and 3-2 are not illustrated. However, according to the analysis results of Example 3-1, the reduced tungsten film 15 tends to be further reduced by increasing the frequency of the supply. On the other hand, the residue from titanium and the residue from chlorine tend to exceed the peaks p and y. Thus, it was found that it may be preferable to supply each of the halogen-containing gas and the reducing gas once instead of repeatedly supplying the halogen-containing gas and the reducing gas multiple times. According to the results of the XPS analysis of Example 3-2, the reduction tends to be effectively performed by increasing the RF power supplied during the removal step. On the other hand, there was no tendency in which the residue is further decreased.

1. A substrate processing method for processing a substrate including a metal layer, the method comprising:
supplying a halogen-containing gas to the substrate and reducing a metal oxide film formed on a surface of the metal layer; and
supplying a reducing gas to the substrate and decreasing a residue remaining on the metal layer by supplying the halogen-containing gas.

2. The substrate processing method of claim 1, wherein the halogen-containing gas is titanium tetrachloride gas.

3. The substrate processing method of claim 1, wherein the reducing gas contains at least one of hydrogen gas or ammonia gas, and
in said decreasing the residue, the reducing gas is turned into plasma and supplied to the substrate.

4. The substrate processing method of claim 3, wherein the substrate is processed in a state where the substrate is placed on a substrate placing table disposed in a processing chamber, and
the plasma of the reducing gas is generated by applying an RF power whose positive voltage is suppressed by a voltage waveform shaping part to the reducing gas supplied to a gap between a lower electrode and an upper electrode, the lower electrode being grounded and constituting the substrate placing table, the upper electrode being disposed in the processing chamber to face the lower electrode and being supplied the RF power from an RF power supply, the voltage waveform shaping part being disposed between the upper electrode and the RF power supply.

5. The substrate processing method of claim 1, wherein in said decreasing the residue, ammonia gas that has not turned into plasma is supplied as the reducing gas to the substrate.

6. The substrate processing method of claim 1, further comprising, after said decreasing the residue, on the assumption that the metal layer forms a bottom surface of a recess formed in an insulator layer and is referred to as a first metal layer, forming a second metal layer in the recess above the first metal layer.

7. The substrate processing method of claim 6, wherein the first metal layer includes a metal selected from ruthenium, tungsten, cobalt, or titanium, and the second metal layer includes a metal selected from ruthenium, tungsten, or molybdenum.

8. The substrate processing method of claim 6, wherein said reducing the metal oxide film and said decreasing the residue are performed in a state where the substrate is accommodated in a first processing chamber maintained in a vacuum atmosphere, and
said forming the second metal layer is performed in a state where the substrate is accommodated in a second processing chamber, which is different from the first processing chamber, maintained in a vacuum atmosphere,
the method further comprising, after said decreasing the residue, transferring the substrate from the first processing chamber to the second processing chamber through a transfer path maintained in a vacuum atmosphere.

9. An apparatus for processing a substrate having a metal layer, comprising:
a processing chamber where the substrate is disposed;
a halogen-containing gas supply part configured to supply a halogen-containing gas into the processing chamber;
a reducing gas supply part configured to supply a reducing gas into the processing chamber; and
a controller,
wherein the controller is configured to output a control signal for executing said supplying a halogen-containing gas to the substrate disposed in the processing chamber and reducing a metal oxide film formed on a surface of the metal layer, and said supplying a reducing gas to the substrate and decreasing a residue remaining on the metal layer by supplying the halogen-containing gas.

10. The apparatus of claim 9, wherein the reducing gas contains at least one of hydrogen gas or ammonia gas, and
the apparatus include:
a lower electrode that is disposed in the processing chamber, constitutes a placing table on which the substrate is placed, and is grounded;
an upper electrode disposed to face the lower electrode;
a radio frequency (RF) power supply configured to apply an RF power to the upper electrode to turn the reducing gas into plasma; and
a voltage waveform shaping part disposed between the RF power supply and the upper electrode and configured to shape a voltage waveform of the RF power to suppress a positive voltage of the RF power applied to the upper electrode.

11. A system for processing a substrate, comprising:
a first apparatus including:
a processing chamber where the substrate is disposed;
a halogen-containing gas supply part configured to supply a halogen-containing gas into the processing chamber;
a reducing gas supply part configured to supply a reducing gas into the processing chamber; and
a controller,
wherein the controller is configured to output a control signal for executing said supplying a halogen-containing gas to the substrate disposed in the processing chamber and reducing a metal oxide film formed on a surface of a first metal layer of the substrate, and said supplying a reducing gas to the substrate and decreasing a residue remaining on the metal layer by supplying the halogen-containing gas;
a second apparatus including a processing chamber for forming a second metal layer; and
a vacuum transfer device including a housing connected to the processing chamber of the first apparatus and the processing chamber of the second apparatus, and a substrate transfer mechanism disposed in the housing to transfer the substrate without exposure to the atmosphere,
wherein the controller is further configured to output a control signal for executing, after said decreasing the residue, allowing the vacuum transfer device to transfer the substrate from the processing chamber of the first apparatus to the processing chamber of the second apparatus, and allowing the second apparatus to form the second metal layer in the recess above the first metal layer where the residue is decreased.

12. The system of claim 11, wherein the first metal layer includes a metal selected from ruthenium, tungsten, or titanium, and
the second metal layer includes a metal selected from ruthenium, tungsten, or molybdenum.
